(19) United States
(12) Patent Application Publication
(10) Pub. No.: US 2025/0015169 A1
(43) Pub. Date: Jan. 9, 2025

(54) ELECTRONIC DEVICE, QUANTUM COMPUTER, AND METHOD FOR MANUFACTURING ELECTRONIC DEVICE

(71) Applicant: FUJITSU LIMITED, Kawasaki-shi (JP)

(72) Inventor: Masayuki HOSODA, Asaka (JP)

(73) Assignee: FUJITSU LIMITED, Kawasaki-shi (JP)

(21) Appl. No.: 18/887,508

(22) Filed: Sep. 17, 2024

Related U.S. Application Data
(63) Continuation of application No. PCT/JP2022/013903, filed on Mar. 24, 2022.

(51) Int. Cl. H01L 29/66; H01L 21/768; H01L 23/14; H01L 23/498

(52) U.S. Cl. CPC H01L 29/66977; H01L 21/76802; H01L 21/76877; H01L 23/147; H01L 23/49888

(57) ABSTRACT

An electronic device includes a first film that is a first layered metal chalcogenide that is single-layered and has a first region and a second region, a second film that overlaps the second region and is a second layered metal chalcogenide that is single-layered or two or more-layered, and an electrode in contact with a laminate of the first film and the second film in the second region.

### CROSS-REFERENCE TO RELATED APPLICATION

This application is a continuation application of International Application PCT/JP2022/013903 filed on Mar. 24, 2022 and designated the U.S., the entire contents of which are incorporated herein by reference.

### FIELD

The embodiments discussed herein are related to an electronic device, a quantum computer, and a method for manufacturing the electronic device.

### BACKGROUND

A quantum computer using Majorana quasiparticles has been studied. As a technique for generating the Majorana quasiparticles, a technique using a two-dimensional topological insulator has been proposed. In this technique, a superconductor is brought into contact with the two-dimensional topological insulator, and a superconducting proximity effect is utilized.

Japanese Laid-open Patent Publication No. 2017-79313 and Japanese Laid-open Patent Publication No. 2017-10971 are disclosed as related art.

### SUMMARY

According to an aspect of the embodiments, an electronic device includes a first film that is a first layered metal chalcogenide that is single-layered and has a first region and a second region, a second film that overlaps the second region and is a second layered metal chalcogenide that is single-layered or two or more-layered, and an electrode in contact with a laminate of the first film and the second film in the second region.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating an electronic device according to a first embodiment;

FIG. 2 is a cross-sectional view (part 1) illustrating a method for manufacturing the electronic device according to the first embodiment;

FIG. 3 is a cross-sectional view (part 2) illustrating the method for manufacturing the electronic device according to the first embodiment;

FIG. 4 is a cross-sectional view (part 3) illustrating the method for manufacturing the electronic device according to the first embodiment;

FIG. 5 is a cross-sectional view (part 4) illustrating the method for manufacturing the electronic device according to the first embodiment;

FIG. 6 is a cross-sectional view (part 5) illustrating the method for manufacturing the electronic device according to the first embodiment;

FIG. 7 is a cross-sectional view (part 6) illustrating the method for manufacturing the electronic device according to the first embodiment;

FIG. 8 is a cross-sectional view (part 7) illustrating the method for manufacturing the electronic device according to the first embodiment;

FIG. 9 is a cross-sectional view illustrating an electronic device according to a second embodiment;

FIG. 10 is a cross-sectional view (part 1) illustrating a method for manufacturing the electronic device according to the second embodiment;

FIG. 11 is a cross-sectional view (part 2) illustrating the method for manufacturing the electronic device according to the second embodiment;

FIG. 12 is a cross-sectional view (part 3) illustrating the method for manufacturing the electronic device according to the second embodiment;

FIG. 13 is a cross-sectional view illustrating an electronic device according to a third embodiment;

FIG. 14 is a cross-sectional view (part 1) illustrating a method for manufacturing the electronic device according to the third embodiment;

FIG. 15 is a cross-sectional view (part 2) illustrating the method for manufacturing the electronic device according to the third embodiment;

FIG. 16 is a cross-sectional view (part 3) illustrating the method for manufacturing the electronic device according to the third embodiment;

FIG. 17 is a top view illustrating a quantum device according to a fourth embodiment;

FIG. 18 is a cross-sectional view illustrating the quantum device according to the fourth embodiment;

FIG. 19 is a cross-sectional view (part 1) illustrating a method for manufacturing the quantum device according to the fourth embodiment;

FIG. 20 is a cross-sectional view (part 2) illustrating the method for manufacturing the quantum device according to the fourth embodiment;

FIG. 21 is a cross-sectional view (part 3) illustrating the method for manufacturing the quantum device according to the fourth embodiment;

FIG. 22 is a cross-sectional view (part 4) illustrating the method for manufacturing the quantum device according to the fourth embodiment;

FIG. 23 is a cross-sectional view (part 5) illustrating the method for manufacturing the quantum device according to the fourth embodiment;

FIG. 24 is a cross-sectional view (part 6) illustrating the method for manufacturing the quantum device according to the fourth embodiment;

FIG. 25 is a top view (part 1) illustrating the method for manufacturing the quantum device according to the fourth embodiment;

FIG. 26 is a top view (part 2) illustrating the method for manufacturing the quantum device according to the fourth embodiment;

FIG. 27 is a top view (part 3) illustrating the method for manufacturing the quantum device according to the fourth embodiment;

FIG. 28 is a top view (part 4) illustrating the method for manufacturing the quantum device according to the fourth embodiment;

FIG. 29 is a top view (part 5) illustrating the method for manufacturing the quantum device according to the fourth embodiment;

FIG. 30 is a top view illustrating a quantum device according to a fifth embodiment;

FIG. 31 is a cross-sectional view illustrating the quantum device according to the fifth embodiment;

FIG. 32 is a cross-sectional view illustrating an electronic device according to a sixth embodiment;

FIG. 33 is a cross-sectional view illustrating an electronic device according to a seventh embodiment;

FIG. 34 is a cross-sectional view illustrating an electronic device according to an eighth embodiment; and

FIG. 35 is a diagram illustrating a quantum computer according to a ninth embodiment.

### DESCRIPTION OF EMBODIMENTS

When the superconductor is brought into contact with the two-dimensional topological insulator, a sufficient superconducting proximity effect may not be obtained.

In addition, it is also conceivable to configure an electronic device by bringing a normal conductor as an electrode into contact with the two-dimensional topological insulator although it is not a technique for generating the Majorana quasiparticles. However, in this case, the contact resistance between the two-dimensional topological insulator and the normal conductor will increase.

An object of the present disclosure is to provide an electronic device, a quantum computer, and a method for manufacturing the electronic device capable of obtaining a favorable junction between an electrode and a two-dimensional topological insulator.

Hereinafter, embodiments of the present disclosure will be specifically described with reference to the accompanying drawings. Note that, in the present description and drawings, constituent elements having substantially the same functional configuration will be denoted with the same reference sign, and redundant descriptions will be sometimes omitted.

### First Embodiment

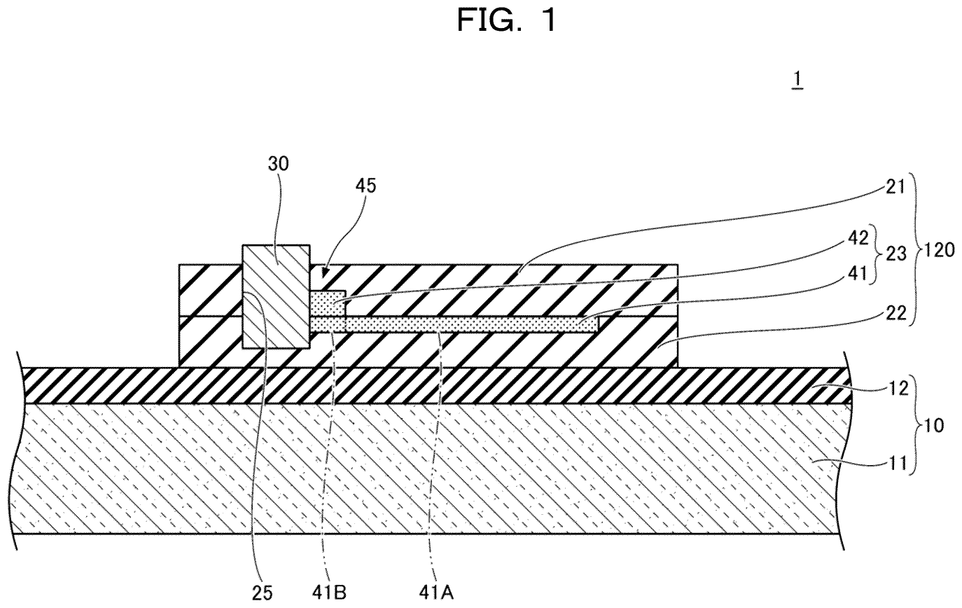

First, a first embodiment will be described. The first embodiment relates to an electronic device. FIG. 1 is a cross-sectional view illustrating an electronic device according to the first embodiment.

As illustrated in FIG. 1, an electronic device 1 according to the first embodiment includes a substrate 10, a laminated structure 120, and an electrode 30. The substrate 10 includes a Si substrate 11 and a Si oxide film 12 formed over the Si substrate 11. The substrate 10 may be an insulating substrate. The laminated structure 120 includes a first protective layer 21, a second protective layer 22, and a topological insulator layer 23.

The first protective layer 21 and the second protective layer 22 contain, for example, hexagonal boron nitride (h-BN). The first protective layer 21 and the second protective layer 22 may be h-BN layers. The h-BN layer is an example of a layered material layer. A thickness of the first protective layer 21 and the second protective layer 22 is, for example, approximately 10 nm to 20 nm. The first protective layer 21 covers one surface (first surface) of the topological insulator layer 23, and the second protective layer 22 covers another surface (second surface) of the topological insulator layer 23. In addition, the first protective layer 21 and the second protective layer 22 are in contact with each other outside an edge of the topological insulator layer 23 over the entire circumference of the topological insulator layer 23. The laminated structure 120 is provided over the substrate 10 with the topological insulator layer 23 placed closer to a side of the substrate 10 than the first protective layer 21. The second protective layer 22 is in contact with the substrate 10.

The topological insulator layer 23 includes a first film 41 and a second film 42. The first film 41 is a single-layered first layered metal chalcogenide. The first layered metal chalcogenide is, for example, 1T′-tungsten ditelluride (WTe₂). The first layered metal chalcogenide may be 1T′-tungsten diselenide (WSe₂) or 1T′-molybdenum ditelluride (MoTe₂). The first film 41 includes a first region 41A and a second region 41B. The first region 41A and the second region 41B are continuous with each other. The second film 42 is a single-layered or two or more-layered second layered metal chalcogenide. The second layered metal chalcogenide is, for example, 1T′-WTe₂. The second layered metal chalcogenide may be 1T′-WSe₂ or 1T′-MoTe₂. The second film 42 is provided over the second region 41B of the first film 41. A laminate 45 is constituted by the second region 41B and the second film 42.

An opening 25 is formed in the laminated structure 120. The opening 25 passes through the first protective layer 21. In addition, a side surface of the laminate 45 is exposed to the opening 25. The opening 25 may reach the second protective layer 22, and a bottom surface of the opening 25 may be placed closer to a side of the substrate 10 than a top surface of the second protective layer 22.

The electrode 30 is provided inside the opening 25. The electrode 30 is in contact with the side surface of the laminate 45, and the side surface of the laminate 45 exposed to the opening 25 is covered with the electrode 30. The electrode 30 may protrude upward from a top surface of the first protective layer 21. The electrode 30 includes, for example, a superconductor or a normal conductor. The electrode 30 contains, for example, aluminum (Al), vanadium (V), tungsten (W), niobium (Nb), an Nb compound, gold (Au), platinum (Pt), or palladium (Pd).

In the electronic device 1, the electrode 30 is in contact with the laminate 45. The layered metal chalcogenide laminate 45 exhibits semimetal or metal electrical conduction properties, unlike two-dimensional topological insulators. Therefore, even in a case where the electrode 30 includes a superconductor or a case where the electrode 30 includes a normal conductor, a favorable junction may be obtained between the electrode 30 and the laminate 45. In addition, the first region 41A functions as a two-dimensional topological insulator, and the second region 41B included in the laminate 45 is continuous with the first region 41A. Therefore, a favorable junction may be obtained between the electrode 30 and the first region 41A functioning as a two-dimensional topological insulator. In addition, it may be easy to secure a large contact area between the electrode 30 and the laminate 45.

Note that the second film 42 is preferably a two or more-layered second layered metal chalcogenide. This is because it is easy to obtain metal electrical conduction properties in the laminate 45.

In addition, the second layered metal chalcogenide may contain molybdenum (Mo), niobium (Nb), tungsten (W), tantalum (Ta), titanium (Ti), zirconium (Zr), iron (Fe), palladium (Pd), iridium (Ir), or platinum (Pt).

In addition, the first film 41 may be placed over the second film 42 in the topological insulator layer 23. For example, the second film 42 may be placed closer to a side of the substrate 10 than the first film 41.

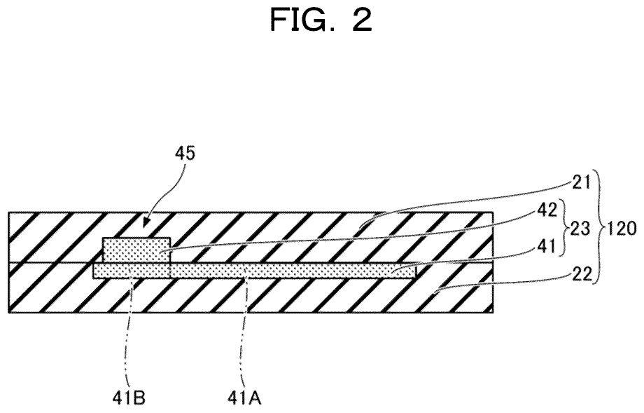

Next, a method for manufacturing the electronic device 1 according to the first embodiment will be described. FIGS. 2 to 8 are cross-sectional views illustrating a method for manufacturing the electronic device 1 according to the first embodiment.

First, as illustrated in FIG. 2, the laminated structure 120 is formed. The laminated structure 120 can be formed by, for example, a stamping method. In the formation of the laminated structure 120, the topological insulator layer 23 including the first film 41 and the second film 42 is prepared in a non-oxidizing atmosphere such as an argon (Ar) atmosphere. The first film 41 and the second film 42 can be acquired, for example, by peeling 1T′-WTe₂ from bulk WTe₂. Then, in a non-oxidizing atmosphere, the second film 42 is attached to the first protective layer 21, and the first film 41 is attached to the first protective layer 21 and the second film 42. At this time, the first region 41A of the first film 41 is attached to the first protective layer 21, and the second region 41B is attached to the second film 42. In this manner, the topological insulator layer 23 including the laminate 45 is prepared. Thereafter, in a non-oxidizing atmosphere, the second protective layer 22 is attached to a surface of the topological insulator layer 23 on a side opposite to a side of the first protective layer 21.

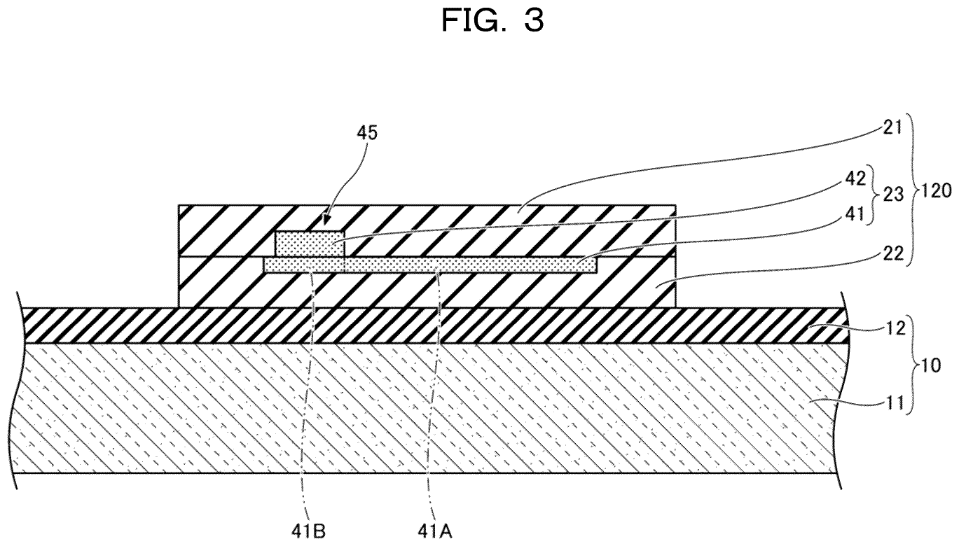

Next, as illustrated in FIG. 3, the laminated structure 120 is provided over the substrate 10 with the topological insulator layer 23 placed closer to a side of the substrate 10 than the first protective layer 21. In the present embodiment, the laminated structure 120 is provided over the substrate 10 such that the second protective layer 22 is in contact with the substrate 10. The laminated structure 120 may be provided over the substrate 10 in the atmosphere. This is because the entire topological insulator layer 23 is covered with the first protective layer 21 and the second protective layer 22, and thus oxidation of the topological insulator layer 23 may be avoided.

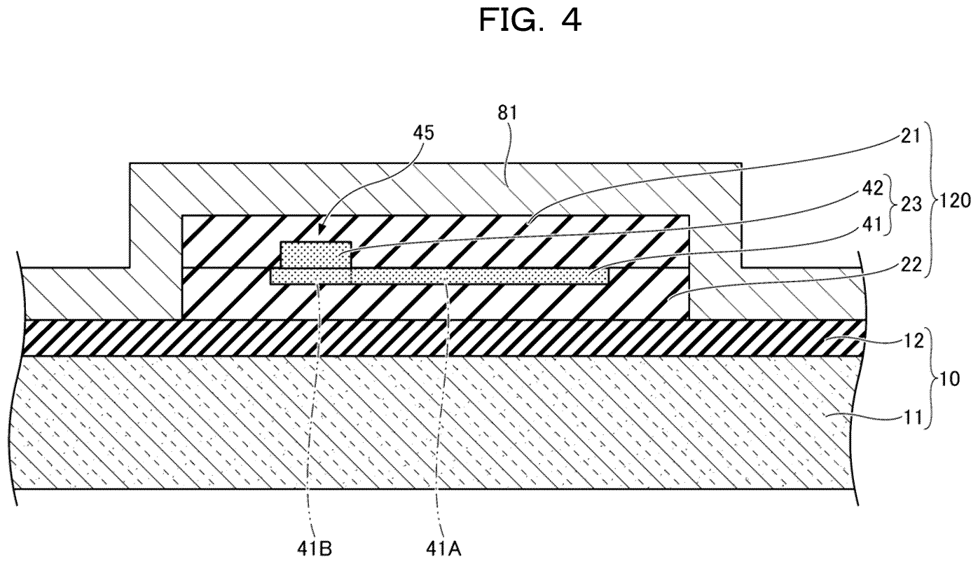

Thereafter, as illustrated in FIG. 4, a sacrificial layer 81 that covers the laminated structure 120 is formed over the substrate 10. The sacrificial layer 81 may be formed by, for example, a vapor deposition method. The sacrificial layer 81 is, for example, an aluminum (Al) layer. The sacrificial layer 81 may be an Au layer. A thickness of the sacrificial layer 81 is preferably equal to or more than 20 nm and, more preferably, equal to or more than 30 nm.

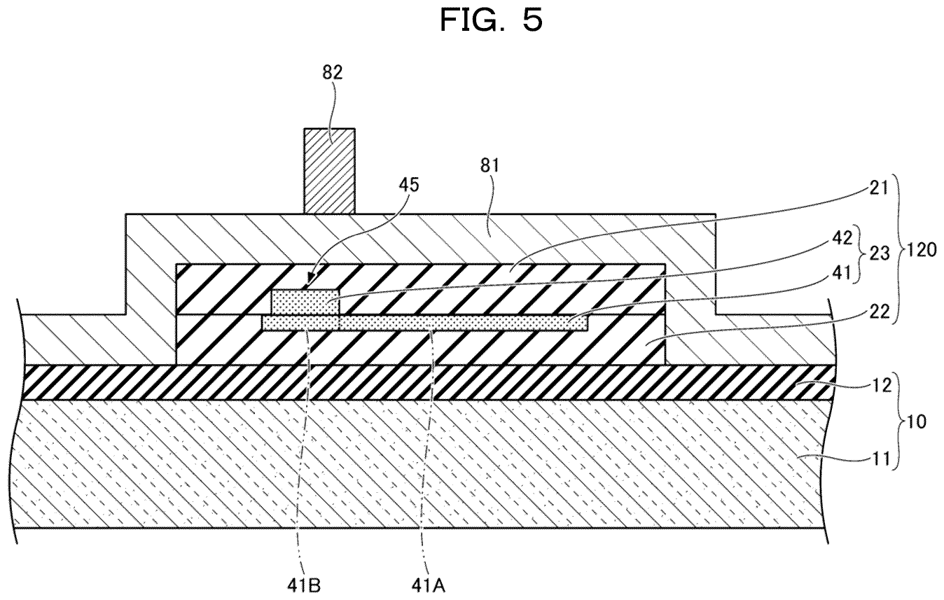

Subsequently, as illustrated in FIG. 5, a protective layer 82 is formed over the sacrificial layer 81. As will be described later, the opening 25 is formed using a focused ion beam (FIB). The protective layer 82 is provided above a portion in which damage caused by irradiation with the FIB at the time of forming the opening 25 is intended to be suppressed. For example, the protective layer 82 is formed above a portion of the topological insulator layer 23 to be left after the formation of the opening 25, around a region where the opening 25 is supposed to be formed. The protective layer 82 is, for example, a platinum (Pt) layer. A thickness of the protective layer 82 is, for example, approximately 20 nm to 50 nm. The protective layer 82 can be formed using, for example, the FIB. When output of the FIB at the time of forming the protective layer 82 is approximately 5 V, damage to the laminated structure 120 may be suppressed by the sacrificial layer 81.

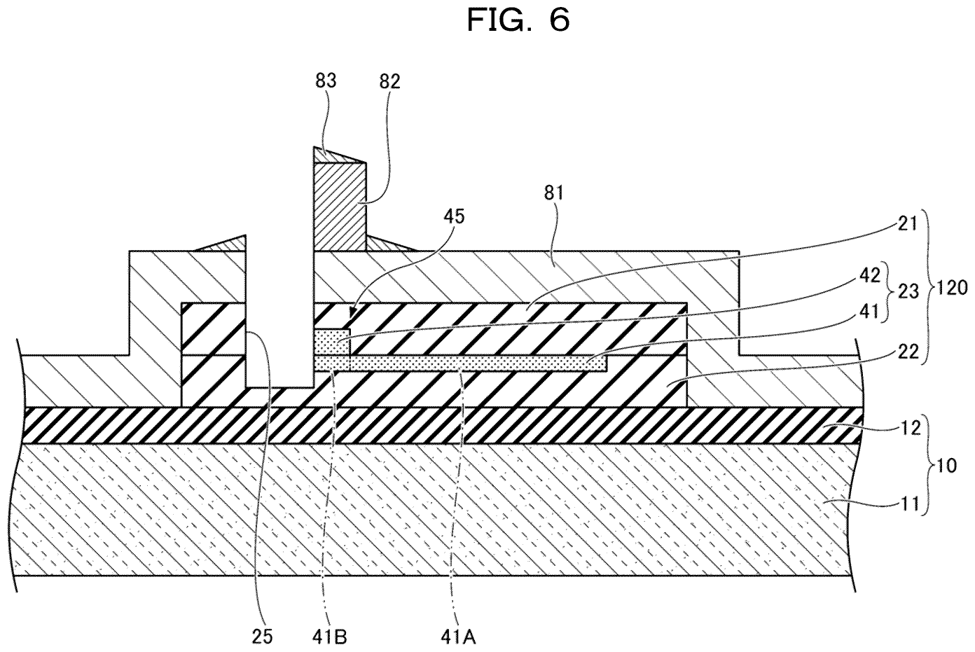

Next, as illustrated in FIG. 6, the opening 25 is formed in the laminated structure 120. The opening 25 can be formed using the FIB in a vacuum, for example. The opening 25 is formed so as to pass through the first protective layer 21 and expose the side surface of the laminate 45. For example, the opening 25 is formed so as to remove a part of the laminate 45. In addition, the second protective layer 22 is exposed to a bottom of the opening 25. Since the protective layer 82 has been formed at the time of forming the opening 25, damage to the topological insulator layer 23 may be suppressed. As illustrated in FIG. 6, a cutting residue 83 may be produced around the opening 25.

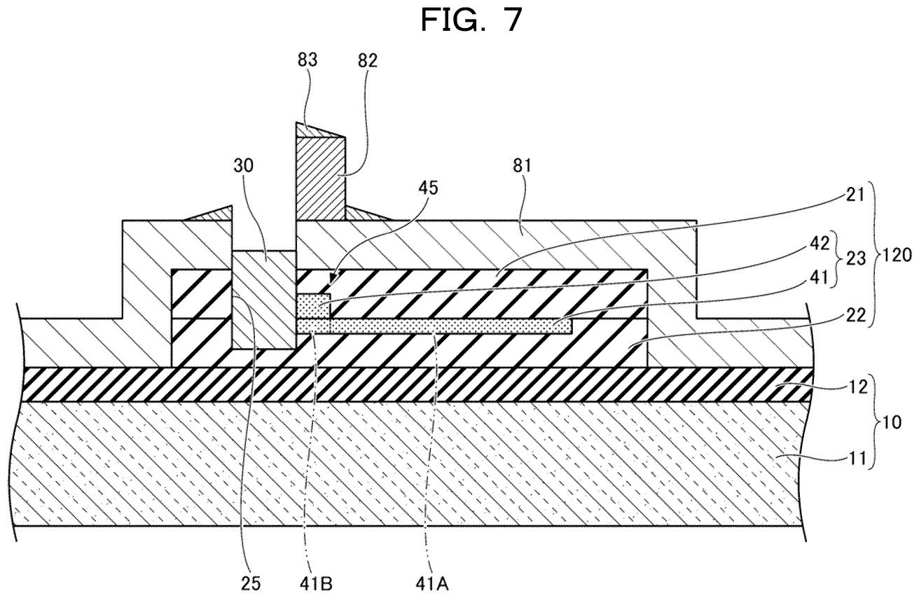

Thereafter, as illustrated in FIG. 7, the electrode 30 is formed inside the opening 25. The electrode 30 can be formed using the FIB in a vacuum, for example. The formation of the opening 25 and the formation of the electrode 30 may be consecutively performed in the same device without exposure to the atmosphere. The electrode 30 is formed to have a thickness enough to cover at least the entire side surface of the laminate 45 exposed to the opening 25. The material of the electrode 30 may adhere to the periphery of the opening 25 at the time of forming the electrode 30.

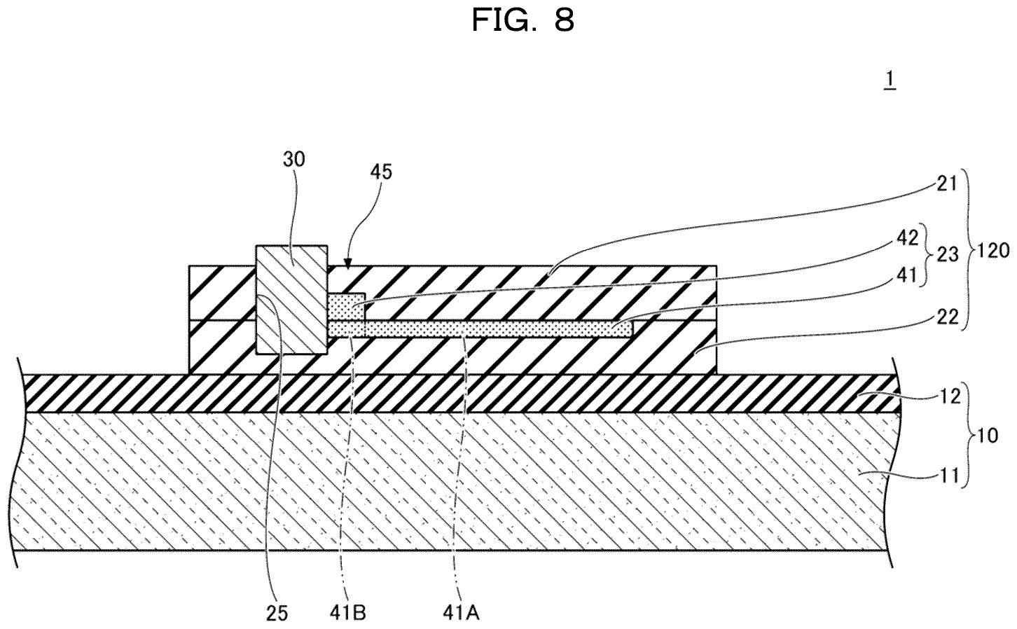

Subsequently, as illustrated in FIG. 8, the sacrificial layer 81 is removed. The protective layer 82 and the cutting residue 83 are also removed along with the removal of the sacrificial layer 81. In a case where the sacrificial layer 81 is an Al layer, the sacrificial layer 81 can be removed using hydrochloric acid. In a case where the sacrificial layer 81 is an Au layer, the sacrificial layer 81 can be removed using a solution containing iodine.

In this manner, the electronic device 1 according to the first embodiment can be manufactured.

Note that the first film 41 and the second film 42 do not have to be separately prepared, and in a case where the topological insulator layer 23 having a shape in which the first film 41 and the second film 42 are integrated is obtained from the bulk WTe₂, such a topological insulator layer 23 may be used.

In addition, even if the second protective layer 22 is not provided, since the first surface of the topological insulator layer 23 is covered with the first protective layer 21, and the second surface is covered with the substrate 10, oxidation of the topological insulator layer 23 may be easily suppressed, and variations in properties associated with the oxidation may be suppressed. In a case where the second protective layer 22 is not used, for example, the first protective layer 21, the first film 41, and the second film 42 are attached to the substrate 10 in a non-oxidizing atmosphere.

### Second Embodiment

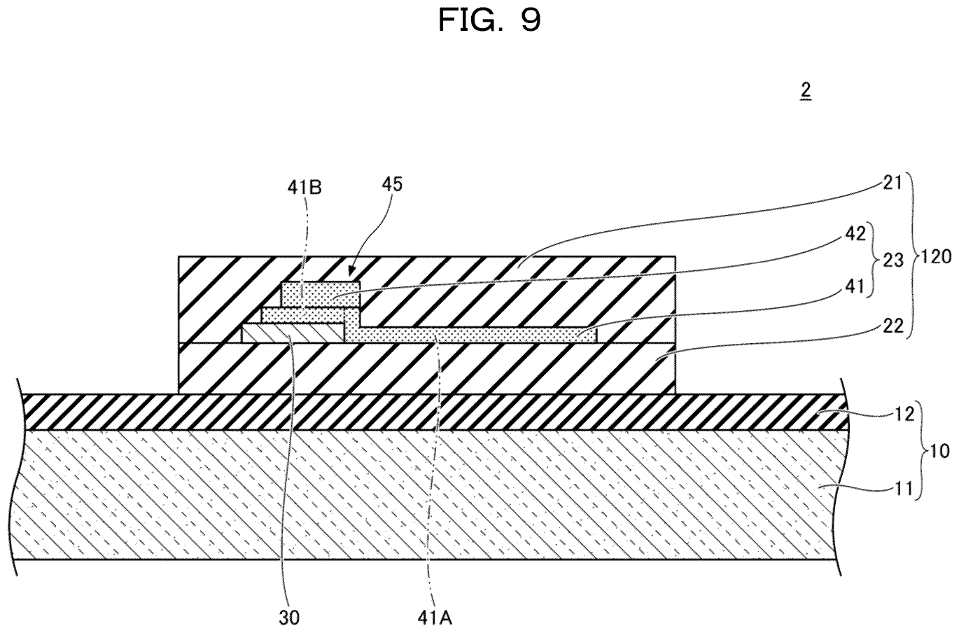

Next, a second embodiment will be described. The second embodiment is different from the first embodiment mainly in arrangement of the electrode 30. FIG. 9 is a cross-sectional view illustrating an electronic device according to the second embodiment.

In an electronic device 2 according to the second embodiment, as illustrated in FIG. 9, an electrode 30 is provided between a laminate 45 and a second protective layer 22. The electrode 30 is in contact with a surface (lower surface) of the laminate 45 on a side of the second protective layer 22. For example, the electrode 30 is in contact with a first film 41. In addition, an opening 25 is not formed in a laminated structure 120.

Other components are similar to those of the first embodiment.

Also in the electronic device 2, the electrode 30 is in contact with the laminate 45. In addition, the first region 41A functions as a two-dimensional topological insulator, and the second region 41B included in the laminate 45 is continuous with the first region 41A. Therefore, a favorable junction may be obtained between the electrode 30 and the first region 41A functioning as a two-dimensional topological insulator.

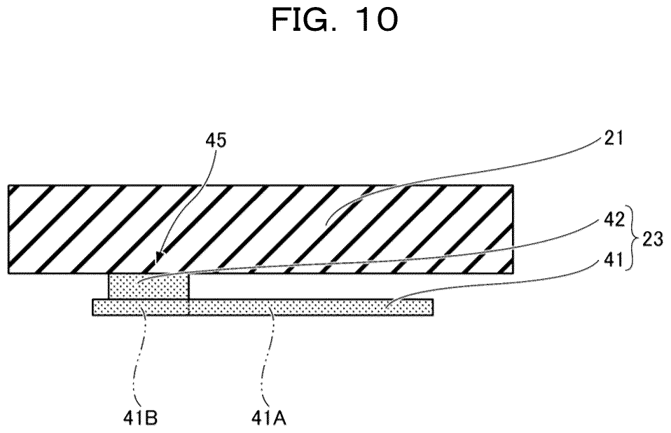

Next, a method for manufacturing the electronic device 2 according to the second embodiment will be described. FIGS. 10 to 12 are cross-sectional views illustrating a method for manufacturing the electronic device 2 according to the second embodiment.

First, as illustrated in FIG. 10, a second film 42 is attached to a first protective layer 21, and the first film 41 is attached to the first protective layer 21 and the second film 42 in a non-oxidizing atmosphere by a stamping method. At this time, the first region 41A of the first film 41 is attached to the first protective layer 21. In this manner, the topological insulator layer 23 including the laminate 45 is prepared.

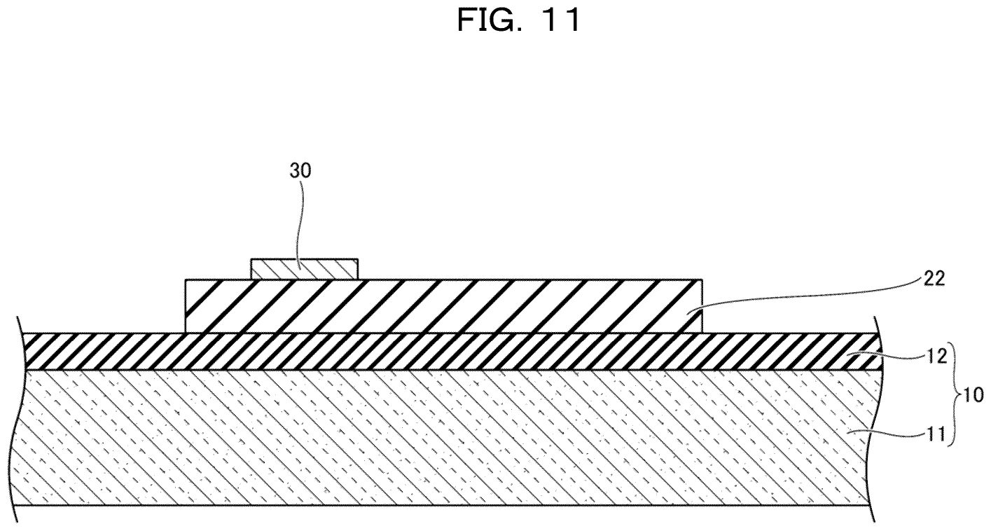

In addition, as illustrated in FIG. 11, the second protective layer 22 is provided over a substrate 10, and the electrode 30 is formed over the second protective layer 22. The electrode 30 can be formed by, for example, a lithography method.

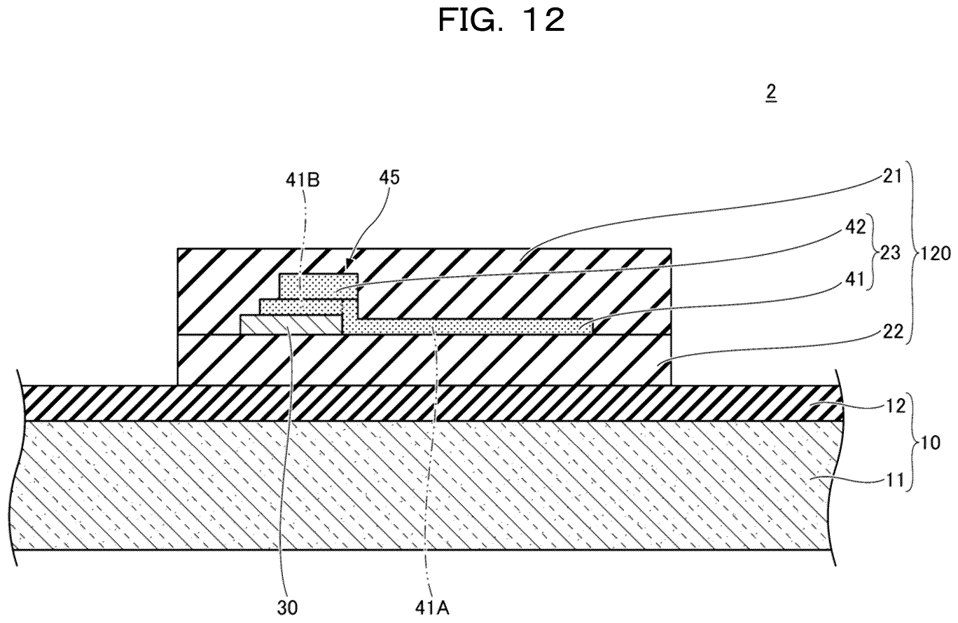

Thereafter, as illustrated in FIG. 12, the first protective layer 21 and the topological insulator layer 23 are attached to the second protective layer 22 in a non-oxidizing atmosphere by a stamping method while keeping the laminate 45 in contact with the electrode 30.

In this manner, the electronic device 2 according to the second embodiment can be manufactured.

Note that, similarly to the first embodiment, the second protective layer 22 may not be provided. In a case where the second protective layer 22 is not used, for example, the electrode 30 is provided over the substrate 10, and the first protective layer 21, the first film 41, and the second film 42 are attached to the substrate 10 in a non-oxidizing atmosphere. In addition, in a case where the second protective layer 22 is provided, the second protective layer 22 and the substrate 10 may be collectively regarded as one substrate.

### Third Embodiment

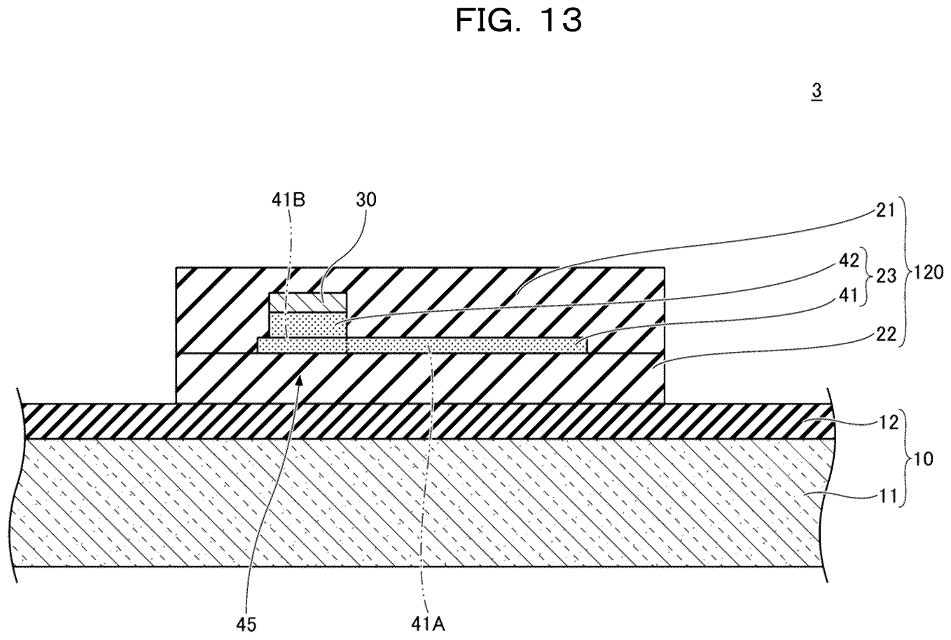

Next, a third embodiment will be described. The third embodiment is different from the first embodiment and the like mainly in arrangement of the electrode 30. FIG. 13 is a cross-sectional view illustrating an electronic device according to the third embodiment.

In an electronic device 3 according to the third embodiment, as illustrated in FIG. 13, an electrode 30 is provided between a laminate 45 and a first protective layer 21. The electrode 30 is in contact with a surface (top surface) of the laminate 45 on a side of the first protective layer 21. For example, the electrode 30 is in contact with a second film 42. In addition, an opening 25 is not formed in a laminated structure 120.

Other components are similar to those of the first embodiment.

Also in the electronic device 3, the electrode 30 is in contact with the laminate 45. In addition, the first region 41A functions as a two-dimensional topological insulator, and the second region 41B included in the laminate 45 is continuous with the first region 41A. Therefore, a favorable junction may be obtained between the electrode 30 and the first region 41A functioning as a two-dimensional topological insulator.

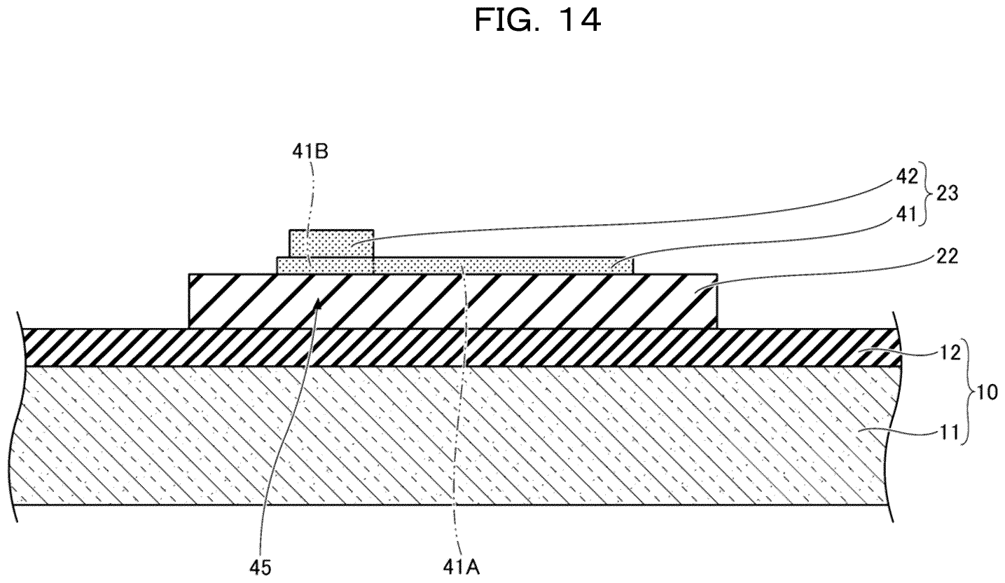

Next, a method for manufacturing the electronic device 3 according to the third embodiment will be described. FIGS. 14 to 16 are cross-sectional views illustrating a method for manufacturing the electronic device 3 according to the third embodiment.

First, as illustrated in FIG. 14, a second protective layer 22, a first film 41, and the second film 42 are provided over a substrate 10 in a non-oxidizing atmosphere by a stamping method.

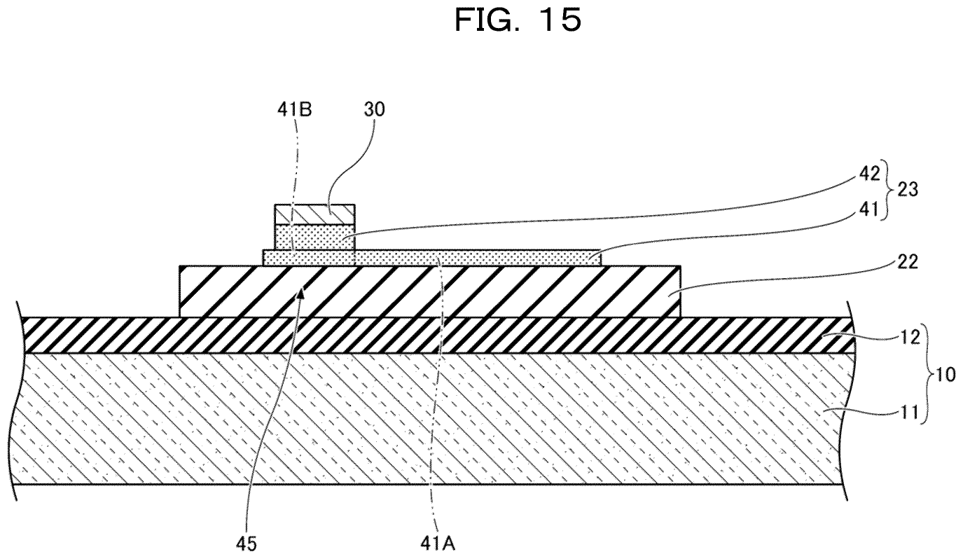

Next, as illustrated in FIG. 15, the electrode 30 is formed over the laminate 45 in a non-oxidizing atmosphere. The electrode 30 can be formed by, for example, a vapor deposition method using a stencil mask or the like.

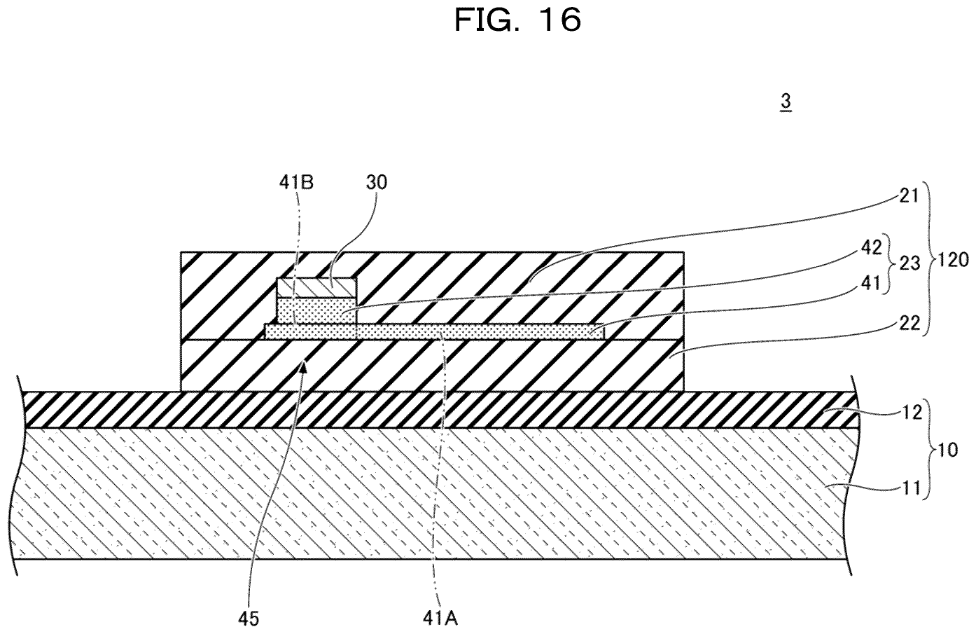

Thereafter, as illustrated in FIG. 16, the first protective layer 21 is attached to the second protective layer 22, a topological insulator layer 23, and the electrode 30 in a non-oxidizing atmosphere by a stamping method.

In this manner, the electronic device 3 according to the third embodiment can be manufactured.

Note that, similarly to the first embodiment, the second protective layer 22 may not be provided. In a case where the second protective layer 22 is not used, for example, the first protective layer 21, the electrode 30, the first film 41, and the second film 42 are attached to the substrate 10 in a non-oxidizing atmosphere. In addition, in a case where the second protective layer 22 is provided, the second protective layer 22 and the substrate 10 may be collectively regarded as one substrate.

### Fourth Embodiment

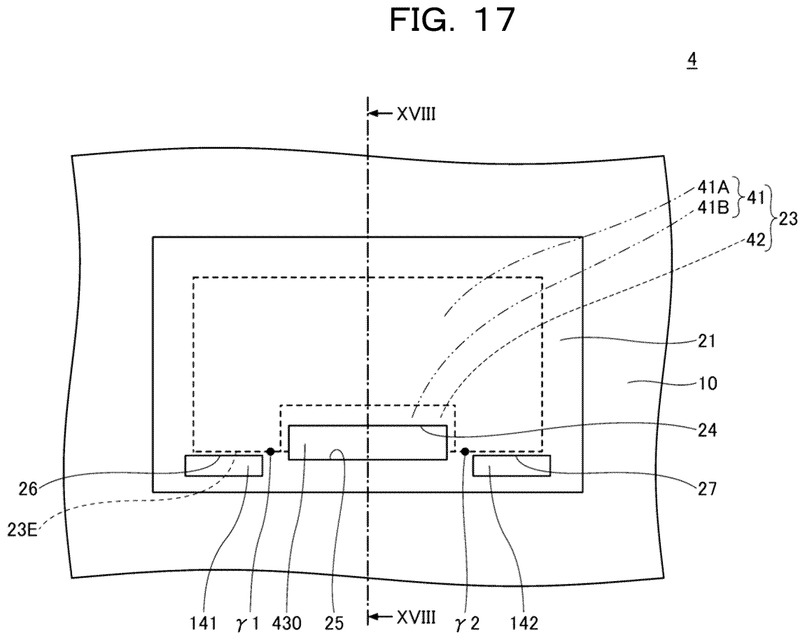

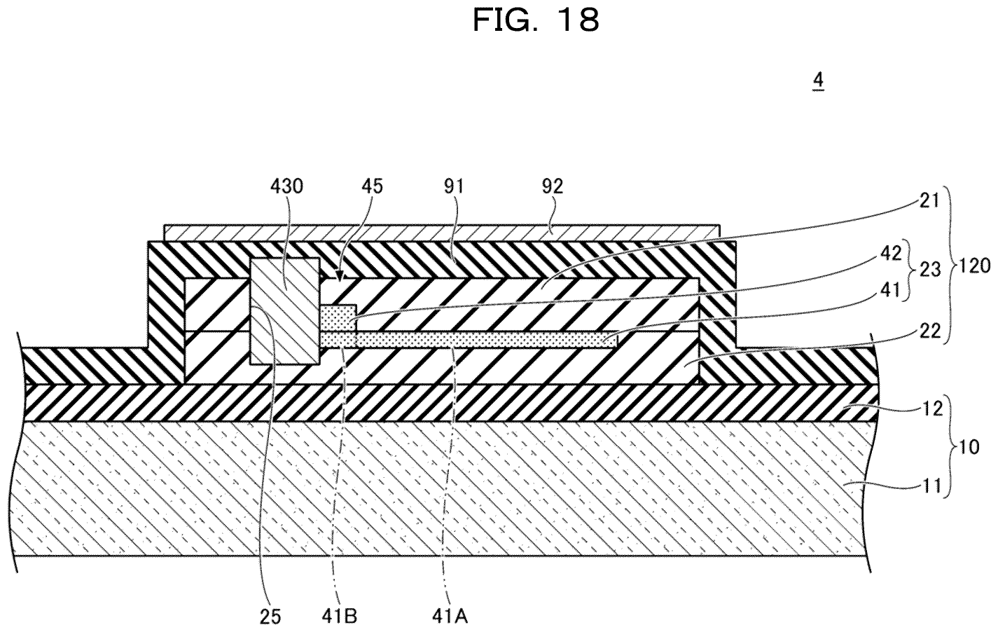

Next, a fourth embodiment will be described. The fourth embodiment relates to a quantum device including a two-dimensional topological insulator. This quantum device is an example of an electronic device. FIG. 17 is a top view illustrating a quantum device according to the fourth embodiment. FIG. 18 is a cross-sectional view illustrating the quantum device according to the fourth embodiment. FIG. 18 corresponds to a cross-sectional view taken along line XVIII-XVIII in FIG. 17.

As illustrated in FIGS. 17 and 18, a quantum device 4 according to the fourth embodiment includes a substrate 10, a laminated structure 120, a superconductor layer 430, magnetic layers 141 and 142, a gate insulating layer 91, and a gate electrode 92. Note that, in FIG. 17, the gate insulating layer 91 and the gate electrode 92 are omitted.

In the quantum device 4, a recess 24 constituting an opening 25 is formed in a topological insulator layer 23 in plan view. In addition, openings 26 and 27 are formed in the laminated structure 120. The openings 26 and 27 pass through a first protective layer 21. The openings 26 and 27 may reach a second protective layer 22, and bottom surfaces of the openings 26 and 27 may be placed closer to a side of the substrate 10 than a top surface of the second protective layer 22. The opening 26 is formed along an edge 23E of a first region 41A so as to be spaced from the opening 25 toward one side. The opening 27 is formed along the edge 23E of the first region 41A so as to be spaced from the opening 25 toward another side. The opening 25 is located between the openings 26 and 27. The openings 26 and 27 are spaced from the edge 23E.

The superconductor layer 430 is provided inside the opening 25. The superconductor layer 430 is in contact with a side surface of the laminate 45, and the side surface of the laminate 45 exposed to the opening 25 is covered with the superconductor layer 430. The superconductor layer 430 may protrude upward from a top surface of the first protective layer 21. The superconductor layer 430 is, for example, a tungsten (W) layer. The superconductor layer 430 is an example of an electrode.

The magnetic layer 141 is provided inside the opening 26. The magnetic layer 142 is provided inside the opening 27. The magnetic layers 141 and 142 generate fields of magnetism extending to the first region 41A. The magnetic layers 141 and 142 are spaced from the edge 23E of the first region 41A and are not in contact with the topological insulator layer 23. The magnetic layers 141 and 142 are, for example, cobalt (Co) layers.

The gate insulating layer 91 is provided over the substrate 10 so as to cover the laminated structure 120 and the superconductor layer 430. The gate electrode 92 is provided over the gate insulating layer 91. The gate insulating layer 91 is a thin film layer of, for example, silicon nitride (Si₃N₄), silicon dioxide (SiO₂), or hexagonal boron nitride. The gate electrode 92 is, for example, a gold (Au) electrode.

Other components are similar to those of the first embodiment.

In the quantum device 4, an edge channel is formed at the edge 23E by an edge state of the first region 41A of the first film 41. Then, a Majorana quasiparticle γ1 is expressed at a portion closer to a side of the magnetic layer 141 than the superconductor layer 430, and a Majorana quasiparticle γ2 is expressed at a portion closer to a side of the magnetic layer 142 than the superconductor layer 430. The Majorana quasiparticle γ1 is restrained in the vicinity of the superconductor layer 430 due to an influence of a magnetic field generated by the magnetic layer 141, and the Majorana quasiparticle γ2 is restrained in the vicinity of the superconductor layer 430 due to an influence of a magnetic field generated by the magnetic layer 142.

In the quantum device 4, the superconductor layer 430 is in contact with the laminate 45. In addition, the first region 41A functions as a two-dimensional topological insulator, and the second region 41B included in the laminate 45 is continuous with the first region 41A. Therefore, a favorable junction may be obtained between the superconductor layer 430 and the first region 41A functioning as a two-dimensional topological insulator.

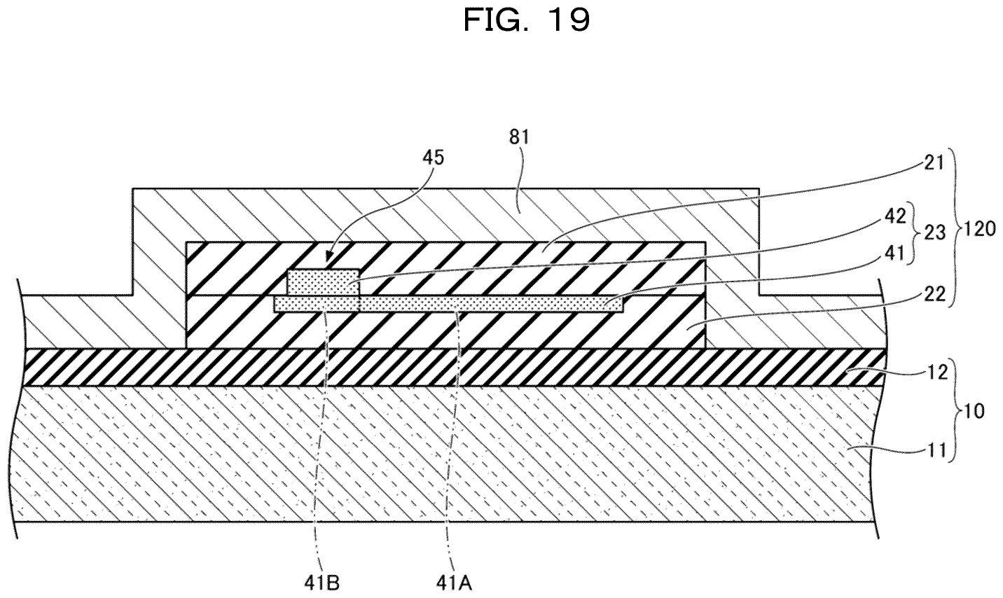

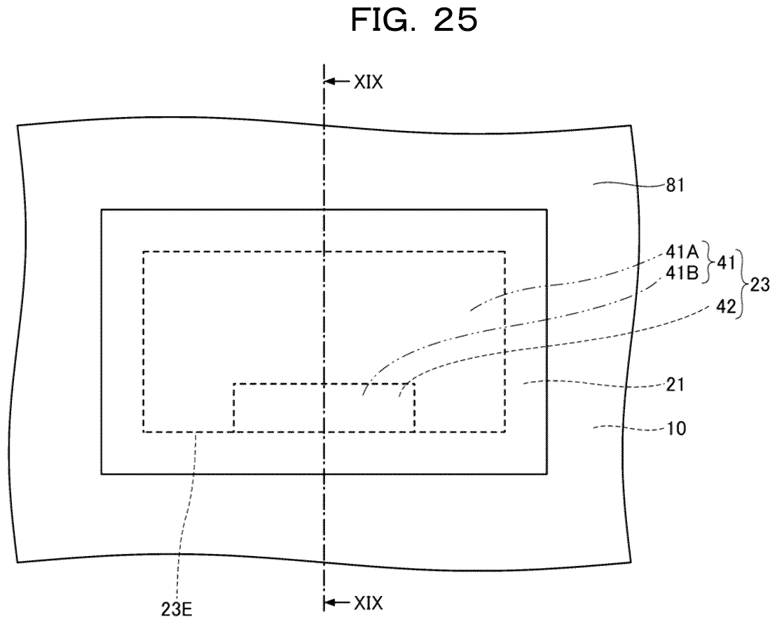

Next, a method for manufacturing the quantum device 4 according to the fourth embodiment will be described. FIGS. 19 to 24 are cross-sectional views illustrating the method for manufacturing the quantum device 4 according to the fourth embodiment. FIGS. 25 to 29 are top views illustrating the method for manufacturing the quantum device 4 according to the fourth embodiment.

First, as illustrated in FIGS. 19 and 25, similarly to the first embodiment, the laminated structure 120 is formed, the laminated structure 120 is provided over the substrate 10 with the topological insulator layer 23 placed closer to a side of the substrate 10 than the first protective layer 21, and the sacrificial layer 81 covering the laminated structure 120 is formed over the substrate 10. FIG. 19 corresponds to a cross-sectional view taken along line XIX-XIX in FIG. 25.

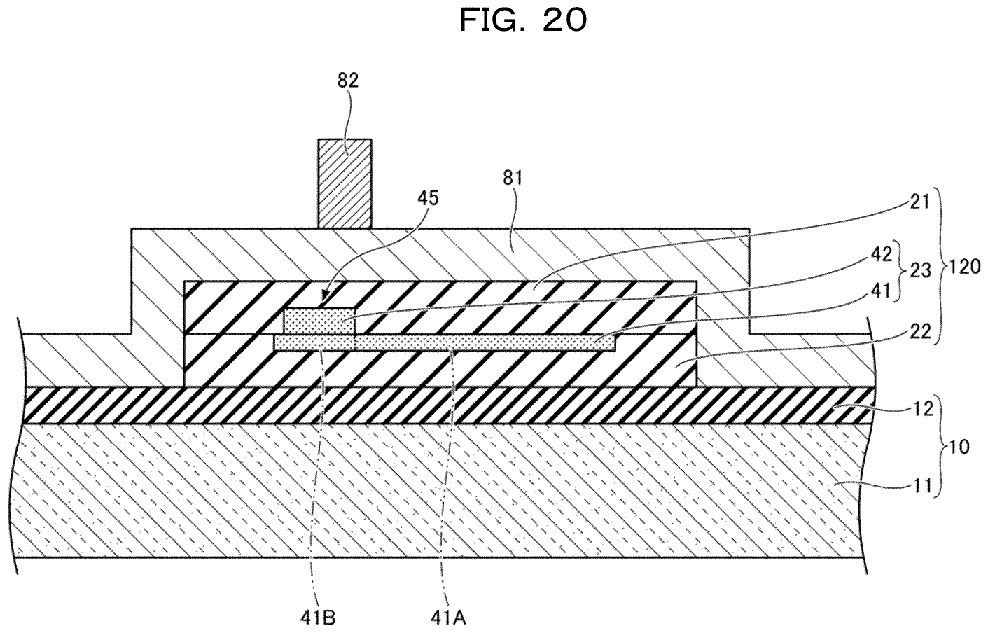

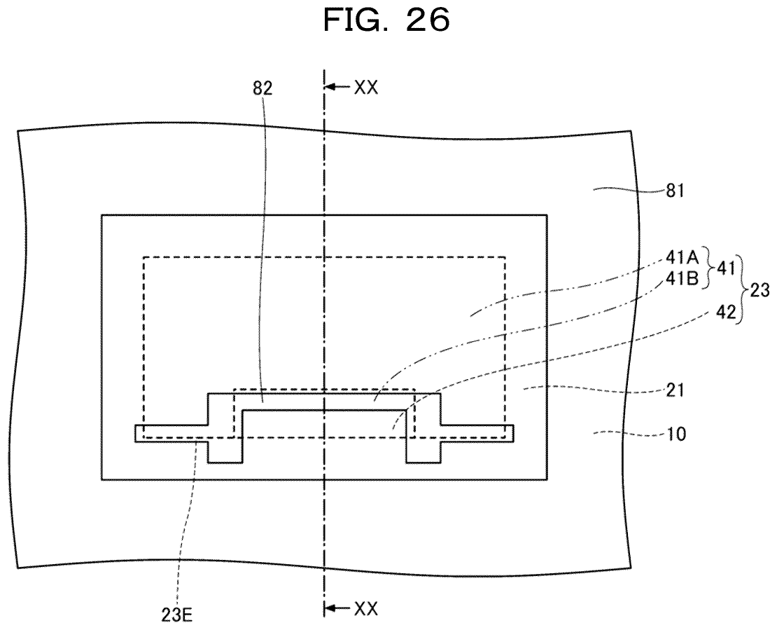

Next, as illustrated in FIGS. 20 and 26, a protective layer 82 is formed over the sacrificial layer 81. As will be described later, the openings 25, 26, and 27 are formed using the FIB. The protective layer 82 is provided above a portion in which damage caused by irradiation with the FIB at the time of forming the openings 25, 26, and 27 is intended to be suppressed. For example, the protective layer 82 is formed above a portion of the topological insulator layer 23 to be left after the formation of the openings 25, 26, and 27, around a region where the openings 25, 26, and 27 are supposed to be formed. The protective layer 82 is, for example, a platinum (Pt) layer. A thickness of the protective layer 82 is, for example, approximately 20 nm to 50 nm. The protective layer 82 can be formed using, for example, the FIB. When output of the FIB at the time of forming the protective layer 82 is approximately 5 V, damage to the laminated structure 120 may be suppressed by the sacrificial layer 81. FIG. 20 corresponds to a cross-sectional view taken along line XX-XX in FIG. 26.

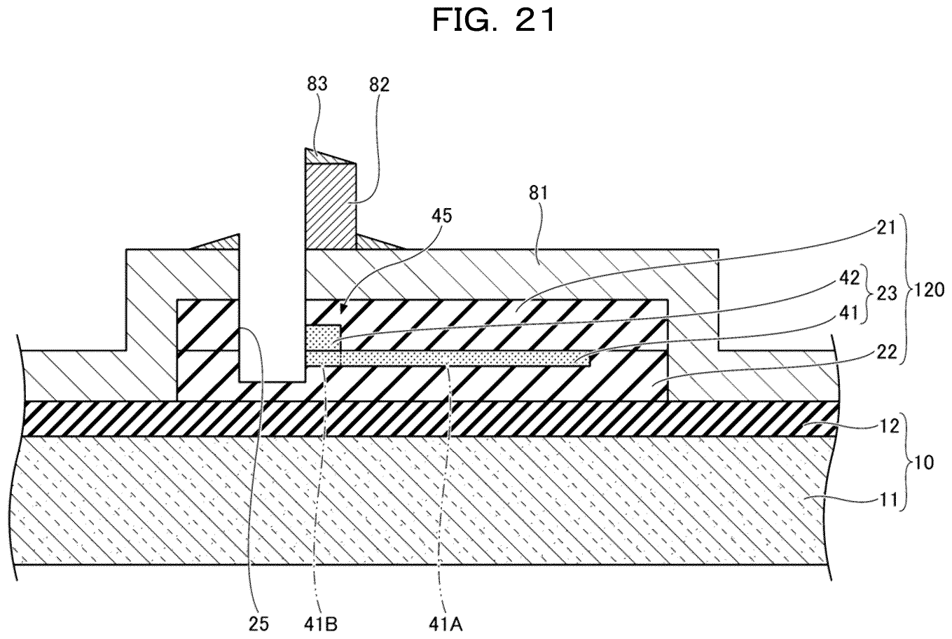

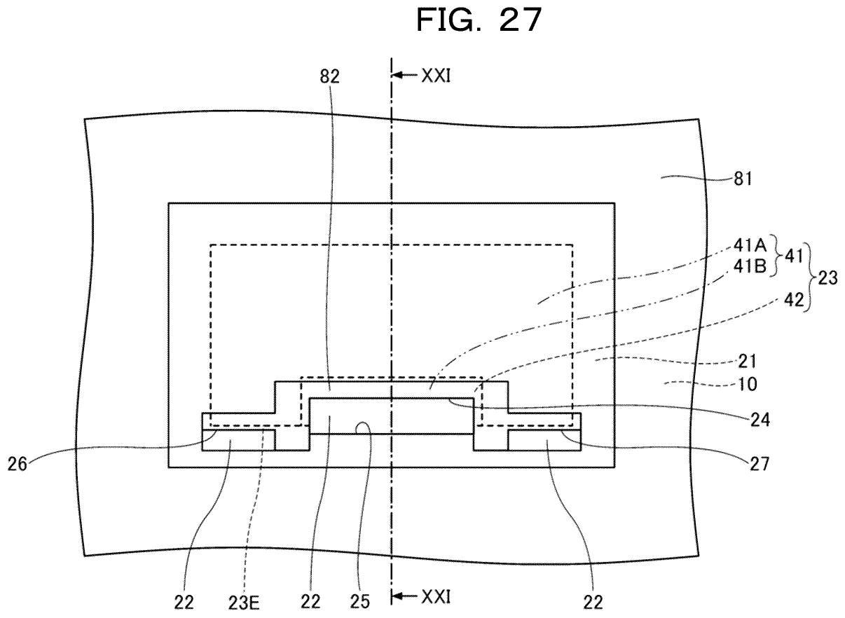

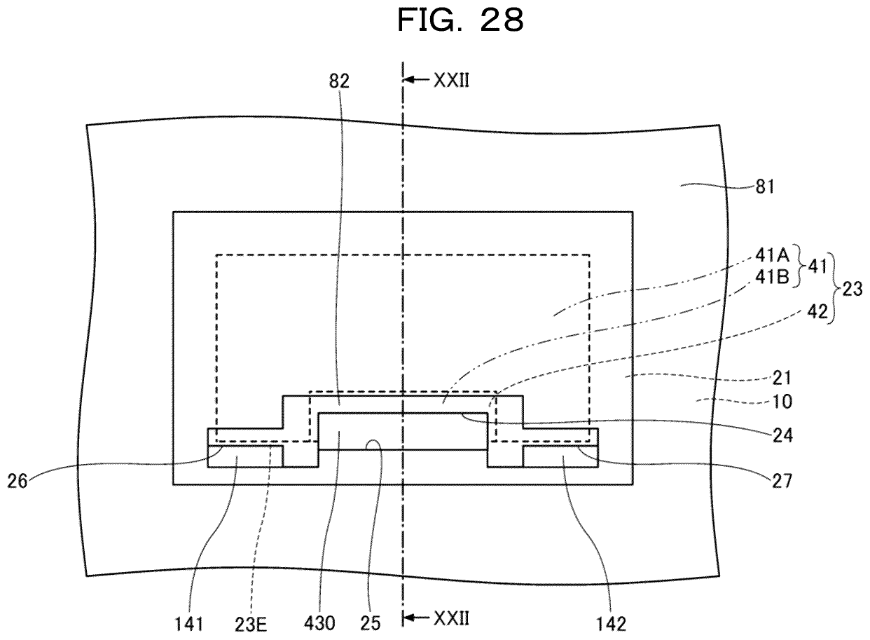

Thereafter, as illustrated in FIGS. 21 and 27, the openings 25, 26, and 27 are formed in the laminated structure 120. The openings 25, 26, and 27 can be formed using the FIB in a vacuum, for example. The opening 25 is formed so as to pass through the first protective layer 21 and expose the side surface of the laminate 45. For example, the opening 25 is formed so as to remove a part of the laminate 45. As a result, the recess 24 constituting the opening 25 is formed in the laminate 45. In addition, the second protective layer 22 is exposed to bottoms of the openings 25, 26, and 27. Since the protective layer 82 has been formed at the time of forming the openings 25, 26, and 27, damage to the topological insulator layer 23 may be suppressed. As illustrated in FIG. 21, a cutting residue 83 may be produced around the openings 25, 26, and 27. The cutting residue 83 is omitted in FIGS. 27 and 28. FIG. 21 corresponds to a cross-sectional view taken along line XXI-XXI in FIG. 27.

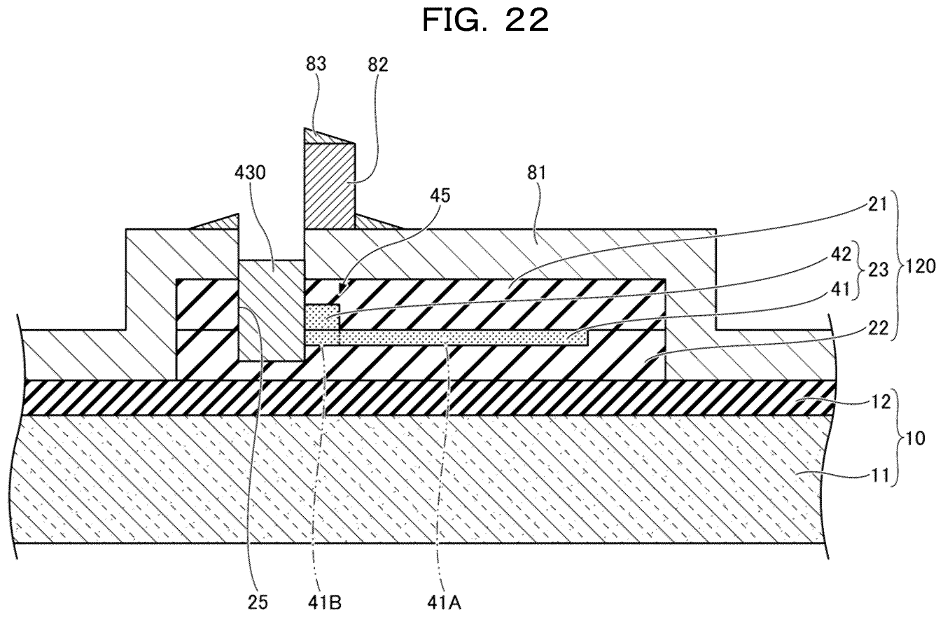

Subsequently, as illustrated in FIGS. 22 and 28, the superconductor layer 430 is formed inside the opening 25. The superconductor layer 430 can be formed using the FIB in a vacuum, for example. The formation of the openings 25, 26, and 27 and the formation of the superconductor layer 430 may be consecutively performed in the same device without exposure to the atmosphere. The superconductor layer 430 is formed to have a thickness enough to cover at least the entire side surface of the laminate 45 exposed to the opening 25. In addition, the magnetic layer 141 is formed inside the opening 26, and the magnetic layer 142 is formed inside the opening 27. The magnetic layers 141 and 142 can be formed using the FIB in a vacuum, for example. The material of the superconductor layer 430 may adhere to the periphery of the opening 25 at the time of forming the superconductor layer 430, the material of the magnetic layer 141 may adhere to the periphery of the opening 26 at the time of forming the magnetic layer 141, and the material of the magnetic layer 142 may adhere to the periphery of the opening 27 at the time of forming the magnetic layer 142. FIG. 22 corresponds to a cross-sectional view taken along line XXII-XXII in FIG. 28.

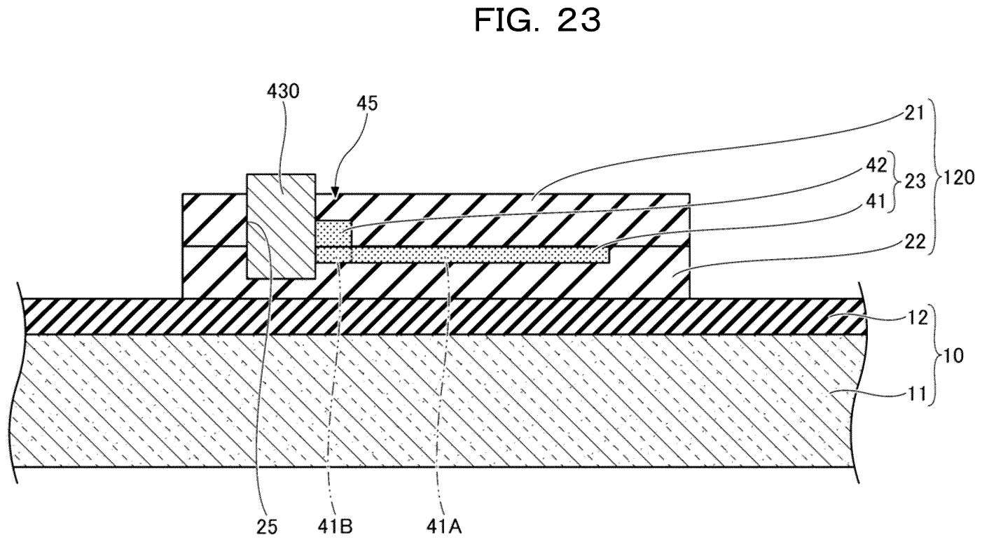

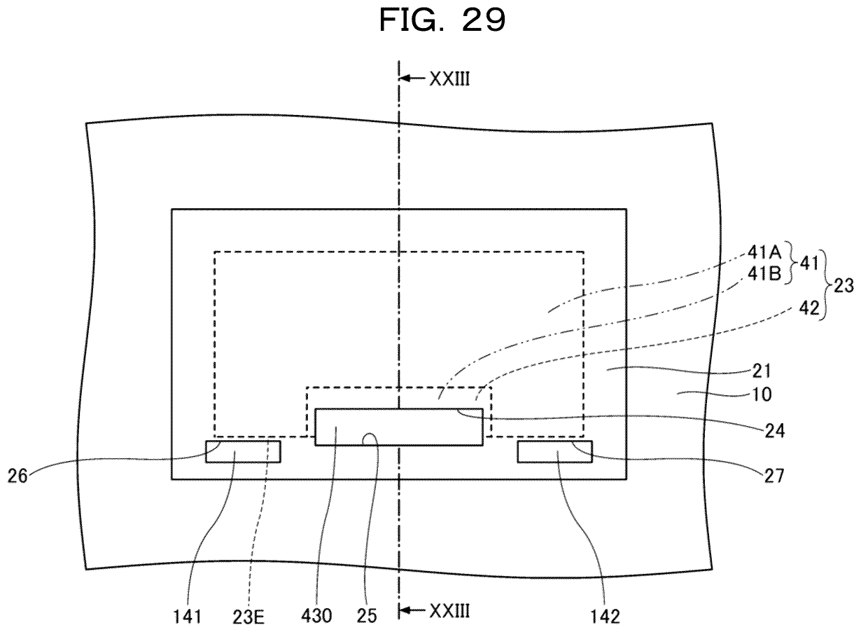

Next, as illustrated in FIGS. 23 and 29, the sacrificial layer 81 is removed. The protective layer 82 and the cutting residue 83 are also removed along with the removal of the sacrificial layer 81. In a case where the sacrificial layer 81 is an Al layer, the sacrificial layer 81 can be removed using hydrochloric acid. In a case where the sacrificial layer 81 is an Au layer, the sacrificial layer 81 can be removed using a solution containing iodine. FIG. 23 corresponds to a cross-sectional view taken along line XXIII-XXIII in FIG. 29.

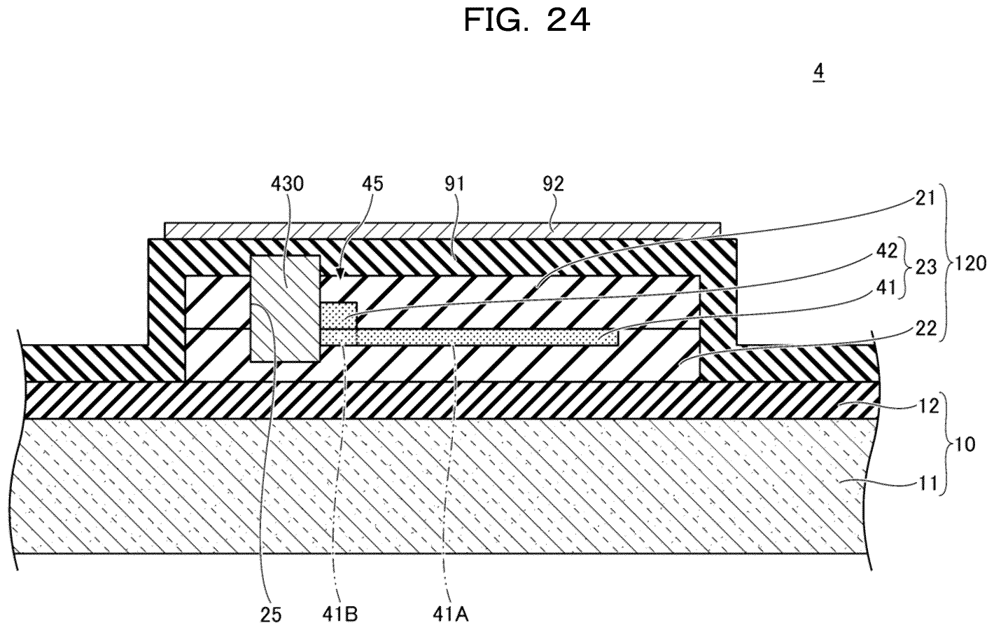

Next, as illustrated in FIG. 24, the gate insulating layer 91 and the gate electrode 92 are formed. The gate insulating layer 91 can be formed by, for example, an atomic layer deposition (ALD) method. The gate electrode 92 can be formed by, for example, vapor deposition using a mask and lift-off by removal of the mask. The gate electrode 92 may be formed by film formation and subsequent etching.

In this manner, the quantum device 4 according to the fourth embodiment can be manufactured.

In the fourth embodiment, the superconductor layer 430 is provided inside the opening 25 and is in contact with the edge 23E of the first region 41A through the laminate 45. Therefore, it may be easy to stably achieve a relationship for expressing the Majorana quasiparticles γ1 and γ2 between the topological insulator layer 23, the superconductor layer 430, and the magnetic layers 141 and 142.

In addition, since the openings 25, 26, and 27 are formed using the FIB, the openings 25, 26, and 27 may be formed with high accuracy. In manufacturing the quantum device 4, if the preparation of the laminated structure 120 and the process from the formation of the opening 25 to the formation of the superconductor layer 430 are performed in a non-oxidizing atmosphere, oxidation of the topological insulator layer 23 may be easily suppressed, and variations in properties associated with the oxidation may be suppressed. Even if cutting residues are produced at the time of forming the openings 25, 26, and 27, since the sacrificial layer 81 is formed prior to the formation of the openings 25, 26, and 27, the cutting residues may be easily removed along with the removal of the sacrificial layer 81. Since the protective layer 82 is formed before the formation of the openings 25, 26, and 27, damage to the laminated structure 120 at the time of forming the openings 25, 26, and 27 may be suppressed.

Note that, even if damage occurs in the vicinity of the side surface of the laminate 45 and a portion where topological properties are deteriorated is produced at the time of forming the opening 25, the topological properties are recovered at an inner side of the portion by several atoms. Therefore, a superconducting proximity effect from the superconductor layer 430 is exerted on the portion where the topological properties are recovered.

In addition, in a case where 1T′-WTe₂ is peeled off from bulk WTe₂, the shapes of the first film 41 and the second film 42 are likely to be different each time the peeling is performed. According to the present embodiment, even if the shapes of the first film 41 and the second film 42 are different each time the peeling is performed, the superconductor layer 430 and the magnetic layers 141 and 142 may be appropriately arranged according to the shape of the topological insulator layer 23.

Note that, even if the second protective layer 22 is not provided, since the first surface of the topological insulator layer 23 is covered with the first protective layer 21, and the second surface is covered with the substrate 10, oxidation of the topological insulator layer 23 may be easily suppressed, and variations in properties associated with the oxidation may be suppressed. In a case where the second protective layer 22 is not used, for example, the first protective layer 21, the first film 41, and the second film 42 are attached to the substrate 10 in a non-oxidizing atmosphere.

### Fifth Embodiment

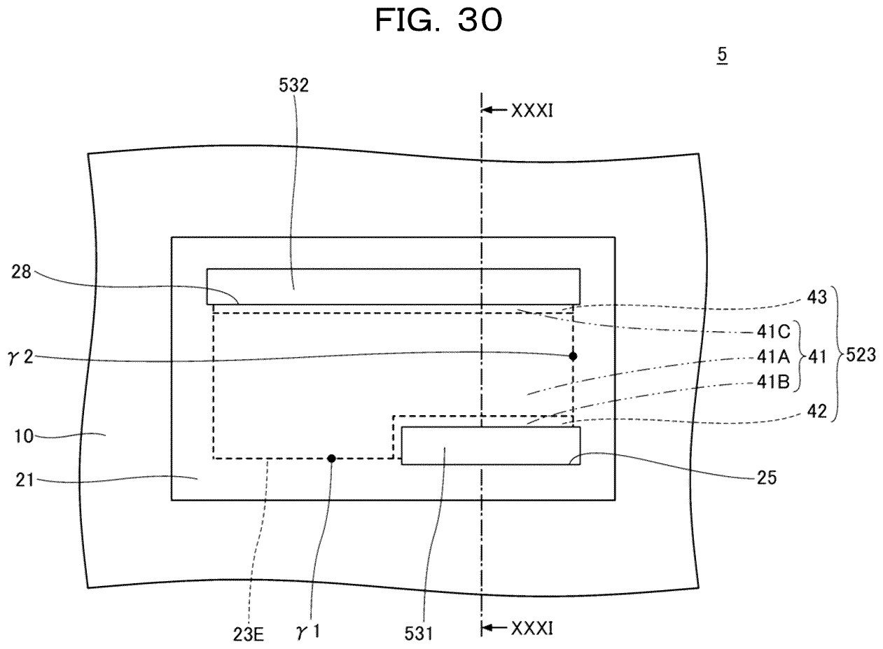

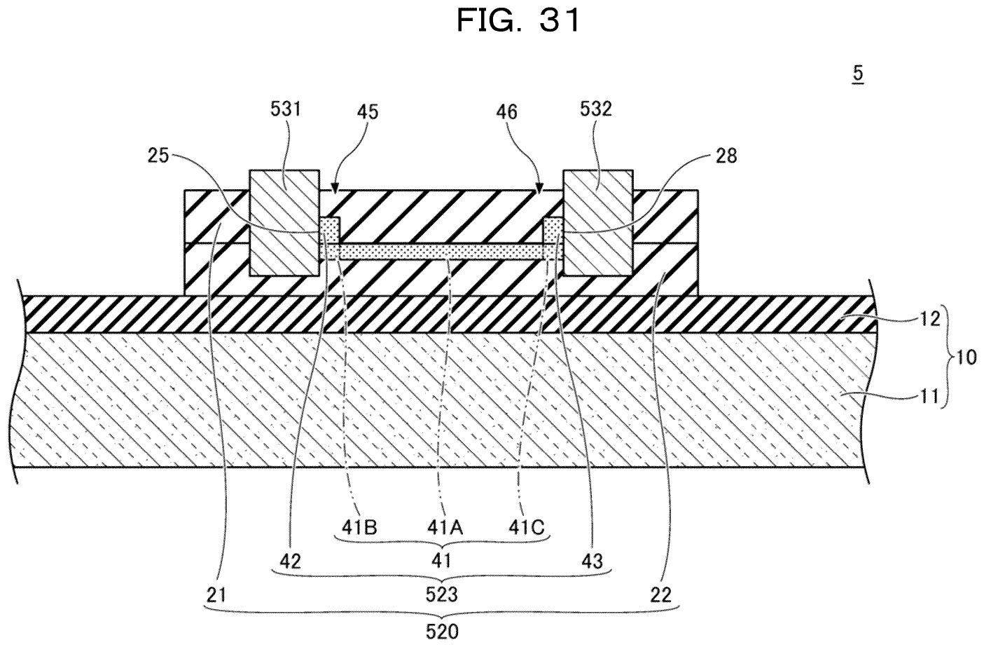

Next, a fifth embodiment will be described. The fifth embodiment relates to a quantum device including a two-dimensional topological insulator. This quantum device is an example of an electronic device. FIG. 30 is a top view illustrating a quantum device according to the fifth embodiment. FIG. 31 is a cross-sectional view illustrating the quantum device according to the fifth embodiment. FIG. 31 corresponds to a cross-sectional view taken along line XXXI-XXXI in FIG. 30.

As illustrated in FIGS. 30 and 31, a quantum device 5 according to the fifth embodiment includes a substrate 10, a laminated structure 520, a superconductor layer 531, and a superconductor layer 532. The laminated structure 520 includes a first protective layer 21, a second protective layer 22, and a topological insulator layer 523.

The first protective layer 21 covers one surface (first surface) of the topological insulator layer 523, and the second protective layer 22 covers another surface (second surface) of the topological insulator layer 523. In addition, the first protective layer 21 and the second protective layer 22 are in contact with each other outside an edge of the topological insulator layer 523 over the entire circumference of the topological insulator layer 523. The laminated structure 520 is provided over the substrate 10 with the topological insulator layer 523 placed closer to a side of the substrate 10 than the first protective layer 21. The second protective layer 22 is in contact with the substrate 10.

The topological insulator layer 523 includes a first film 41, a second film 42, and a third film 43. The first film 41 includes a first region 41A, a second region 41B, and a third region 41C. The first region 41A, the second region 41B, and the third region 41C are continuous with each other. The first region 41A is placed between the second region 41B and the third region 41C. Similarly to the second film 42, the third film 43 is made up of a single-layered or two or more-layered second layered metal chalcogenide. The third film 43 is provided over the third region 41C of the first film 41. A laminate 46 constituted by the third region 41C and the third film 43.

Openings 25 and 28 are formed in the laminated structure 520. The openings 25 and 28 pass through the first protective layer 21. In addition, a side surface of the laminate 45 is exposed to the opening 25, and a side surface of the laminate 46 is exposed to the opening 28. The openings 25 and 28 may reach the second protective layer 22, and bottom surfaces of the openings 25 and 28 may be placed closer to a side of the substrate 10 than a top surface of the second protective layer 22.

The superconductor layer 531 is provided inside the opening 25. The superconductor layer 531 is in contact with the side surface of the laminate 45, and the side surface of the laminate 45 exposed to the opening 25 is covered with the superconductor layer 531. The superconductor layer 531 may protrude upward from a top surface of the first protective layer 21. The superconductor layer 532 is provided inside the opening 28. The superconductor layer 532 is in contact with the side surface of the laminate 46, and the side surface of the laminate 46 exposed to the opening 28 is covered with the superconductor layer 532. The superconductor layer 532 may protrude upward from a top surface of the first protective layer 21. The superconductor layers 531 and 532 are, for example, tungsten (W) layers. The superconductor layers 531 and 532 are examples of the electrode.

In the quantum device 5, the superconductor layer 531 is in contact with the laminate 45, and the superconductor layer 532 is in contact with the laminate 46. In addition, the first region 41A functions as a two-dimensional topological insulator, and the second region 41B included in the laminate 45 and the third region 41C included in the laminate 46 are continuous with the first region 41A. Therefore, a favorable junction may be obtained between the superconductor layers 531 and 532 and the first region 41A functioning as a two-dimensional topological insulator.

In addition, according to the quantum device 5, a Josephson junction (topological Josephson junction) involving the Majorana quasiparticles is obtained. Therefore, evidence of unknown expression of the Majorana quasiparticles may be found through the measurement using the topological Josephson junction.

### Sixth Embodiment

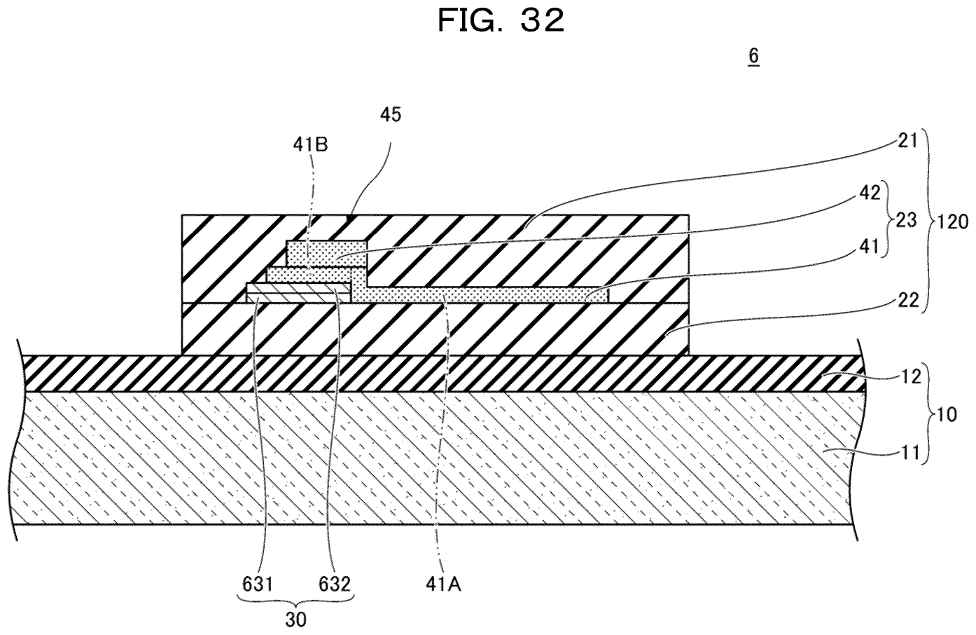

Next, a sixth embodiment will be described. The sixth embodiment is different from the second embodiment mainly in a configuration of an electrode. FIG. 32 is a cross-sectional view illustrating an electronic device according to the sixth embodiment.

In an electronic device 6 according to the sixth embodiment, an electrode 30 includes a superconductor layer 631 and a normal conductor layer 632. The superconductor layer 631 is in contact with a second protective layer 22, and the normal conductor layer 632 is in contact with a laminate 45. For example, the superconductor layer 631 is a tungsten (W) layer, and the normal conductor layer 632 is a platinum (Pt) layer or a palladium (Pd) layer. For example, a thickness of the normal conductor layer 632 is approximately 1 nm to 10 nm and, preferably, approximately 2 nm to 5 nm.

Other components are similar to those of the second embodiment.

Effects similar to those of the second embodiment may be obtained also in the sixth embodiment. In addition, in a case where the normal conductor layer 632 is a platinum layer, it may be easy to reduce the contact resistance between the electrode 30 and a topological insulator layer 23. In addition, in a case where the normal conductor layer 632 is a palladium (Pd) layer, the properties of the superconductor can be obtained at a portion where the laminate 45 and the normal conductor layer 632 are in contact.

### Seventh Embodiment

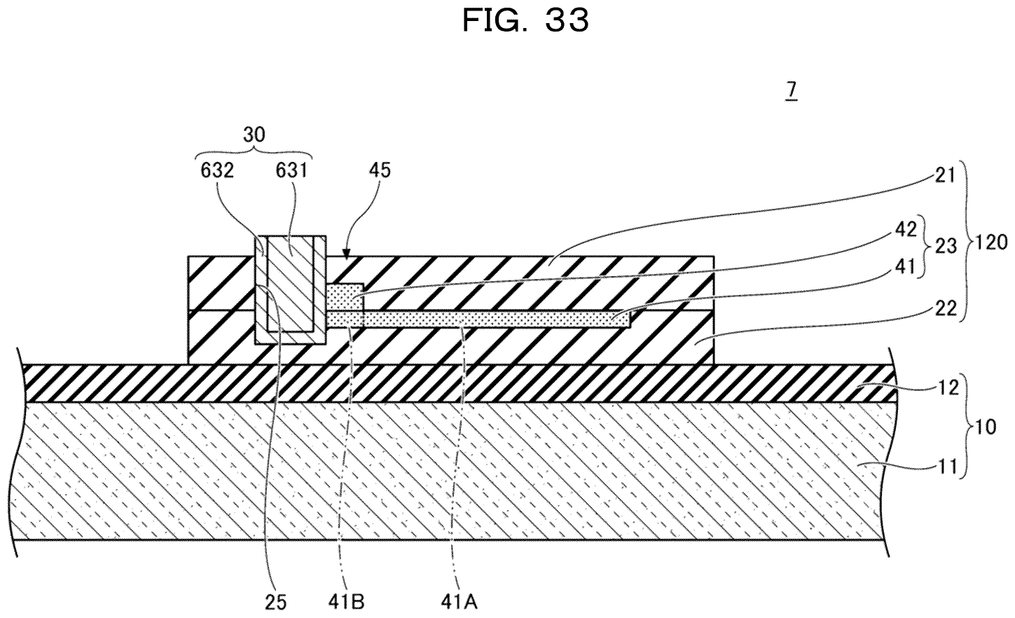

Next, a seventh embodiment will be described. The seventh embodiment is different from the first embodiment mainly in a configuration of an electrode. FIG. 33 is a cross-sectional view illustrating an electronic device according to the seventh embodiment.

In an electronic device 7 according to the seventh embodiment, an electrode 30 includes a superconductor layer 631 and a normal conductor layer 632. The normal conductor layer 632 is in contact with a bottom surface and a side wall surface of an opening 25, and the superconductor layer 631 is provided on an inner side of the normal conductor layer 632. The normal conductor layer 632 is in contact with a laminate 45.

Other components are similar to those of the first embodiment.

Effects similar to those of the first embodiment may be obtained also in the seventh embodiment. In addition, in a case where the normal conductor layer 632 is a platinum layer, it may be easy to reduce the contact resistance between the electrode 30 and a topological insulator layer 23. In addition, in a case where the normal conductor layer 632 is a palladium (Pd) layer, the properties of the superconductor can be obtained at a portion where the laminate 45 and the normal conductor layer 632 are in contact.

Note that the normal conductor layer 632 can be formed by, for example, vapor deposition from a direction inclined from a direction perpendicular to a top surface of the substrate 10. In addition, the normal conductor layer 632 may be formed by a sputtering method.

### Eighth Embodiment

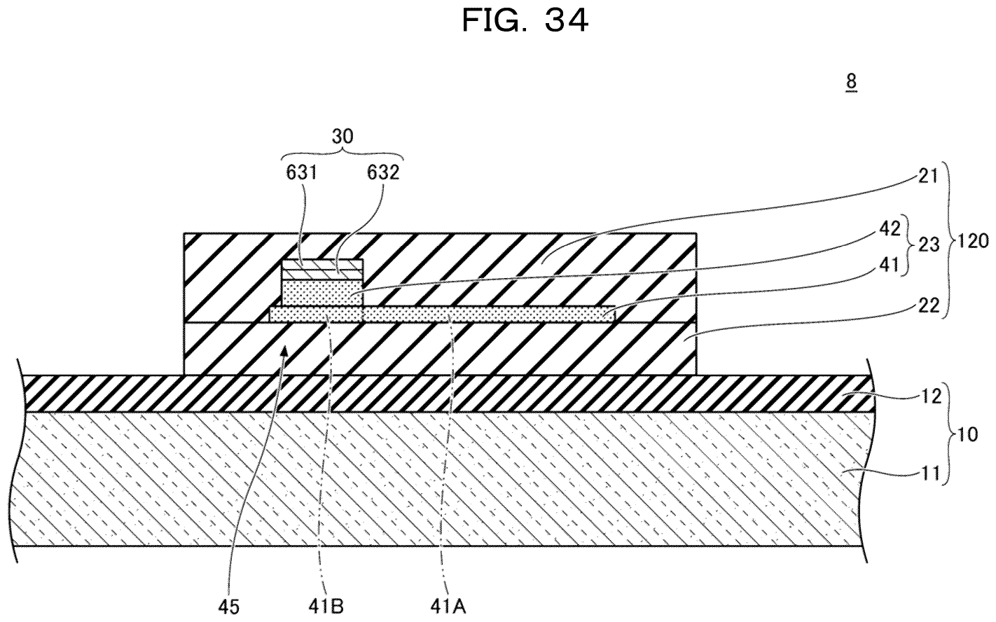

Next, an eighth embodiment will be described. The eighth embodiment is different from the third embodiment mainly in a configuration of an electrode. FIG. 34 is a cross-sectional view illustrating an electronic device according to the eighth embodiment.

In an electronic device 8 according to the eighth embodiment, an electrode 30 includes a superconductor layer 631 and a normal conductor layer 632. The superconductor layer 631 is in contact with a first protective layer 21, and the normal conductor layer 632 is in contact with a laminate 45.

Other components are similar to those of the third embodiment.

Effects similar to those of the third embodiment may be obtained also in the eighth embodiment. In addition, in a case where the normal conductor layer 632 is a platinum layer, it may be easy to reduce the contact resistance between the electrode 30 and a topological insulator layer 23. In addition, in a case where the normal conductor layer 632 is a palladium (Pd) layer, the properties of the superconductor can be obtained at a portion where the laminate 45 and the normal conductor layer 632 are in contact.

### Ninth Embodiment

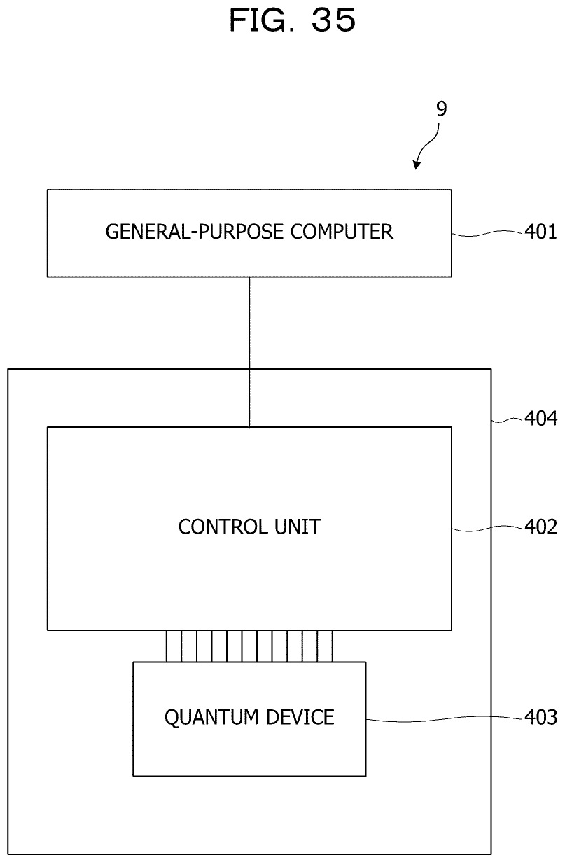

Next, a ninth embodiment will be described. The ninth embodiment relates to a quantum computer. FIG. 35 is a diagram illustrating a quantum computer according to the ninth embodiment.

A quantum computer 9 according to the ninth embodiment includes a general-purpose computer 401, a control unit 402, and a quantum device 403. The control unit 402 controls the quantum device 403, based on a control signal from the general-purpose computer 401. The quantum device according to the fourth embodiments is used as the quantum device 403, for example. The control unit 402 and the quantum device 403 are housed in a cryostat 404.

With the quantum computer 9, a stable quantum operation may be performed.

Although the preferred embodiments and the like have been described in detail so far, the embodiments are not limited to the above-described embodiments and the like, and various modifications and substitutions can be made to the embodiments and the like described above, without departing from the scope disclosed in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device comprising:
a first film that is a first layered metal chalcogenide that is single-layered and has a first region and a second region;
a second film that overlaps the second region and is a second layered metal chalcogenide that is single-layered or two or more-layered; and
an electrode in contact with a laminate of the first film and the second film in the second region.

2. The electronic device according to claim 1, wherein
the second film is the second layered metal chalcogenide that is two or more-layered.

3. The electronic device according to claim 1, wherein
the first layered metal chalcogenide is 1T′-tungsten ditelluride (WTe₂).

4. The electronic device according to any one of claims 1, wherein
the second layered metal chalcogenide contains molybdenum (Mo), niobium (Nb), tungsten (W), tantalum (Ta), titanium (Ti), zirconium (Zr), iron (Fe), palladium (Pd), iridium (Ir), or platinum (Pt).

5. The electronic device according to claim 1, wherein
the electrode includes a superconductor.

6. The electronic device according to claim 1, wherein
the electrode includes a normal conductor.

7. The electronic device according to claim 1, wherein
the electrode contains aluminum (Al), vanadium (V), W, Nb, an Nb compound, gold (Au), Pt, or Pd.

8. The electronic device according to claim 1, wherein
directions of crystal axes are different from each other between the first film and the second film.

9. The electronic device according to claim 1, wherein
the electrode is in contact with a surface of the second region parallel to the first film.

10. The electronic device according to claim 1, wherein
the electrode is in contact with a surface of the second film parallel to the first film.

11. The electronic device according to claim 1, wherein
the electrode is in contact with a side surface of the laminate.

12. The electronic device according to claim 11, further comprising:
a substrate; and
a first protective layer provided above the substrate, wherein
the first film and the second film are sandwiched between the substrate and the first protective layer,
an opening that exposes the side surface of the laminate is formed in the first protective layer, and
the electrode is provided inside the opening.

13. The electronic device according to claim 12, wherein
the first protective layer contains hexagonal boron nitride.

14. The electronic device according to claim 12, further comprising:
a second protective layer provided between the substrate, and the first film and the second film.

15. The electronic device according to claim 14, wherein
the second protective layer contains hexagonal boron nitride.

16. A quantum computer including an electronic device, the electric device comprising:
a first film that is a first layered metal chalcogenide that is single-layered and has a first region and a second region;
a second film that overlaps the second region and is a second layered metal chalcogenide that is single-layered or two or more-layered; and
an electrode in contact with a laminate of the first film and the second film in the second region.

17. A method for manufacturing an electronic device, the method comprising:
preparing a first film that is a first layered metal chalcogenide that is single-layered and has a first region and a second region; and a second film that overlaps the second region and is a second layered metal chalcogenide that is single-layered or two or more-layered; and
providing an electrode in contact with a laminate of the first film and the second film in the second region.

18. The method according to claim 17, wherein
the preparing the first film and the second film includes attaching the first film and the second film to a first protective layer in a non-oxidizing atmosphere, and
the providing the electrode includes forming an opening through which a side surface of the laminate is exposed, in the first protective layer in the non-oxidizing atmosphere, and forming the electrode inside the opening in the non-oxidizing atmosphere.

19. The method according to claim 17, wherein
the preparing the first film and the second film includes attaching the first film and the second film to a first protective layer in a non-oxidizing atmosphere, and
the providing the electrode includes:
forming the electrode above a substrate; and
attaching the first protective layer, the first film, and the second film to the substrate while keeping the laminate in contact with the electrode in the non-oxidizing atmosphere.

20. The method according to claim 17, wherein
the preparing the first film and the second film includes attaching the first film and the second film over a substrate in a non-oxidizing atmosphere,
the providing the electrode includes forming the electrode over the laminate in the non-oxidizing atmosphere, and
attaching a first protective layer to the electrode, the first film, the second film, and the substrate in the non-oxidizing atmosphere.
